(19) United States
(12) Patent Application Publication
(10) Pub. No.: US 2015/0061686 A1
(43) Pub. Date: Mar. 5, 2015

(54) Method for detecting lithium battery

(71) Applicant: Chung-Shan Institute of Science and Technology, Longtan (TW)

(72) Inventors: Yu-Min Liao, Longtan (TW); Kuo-Kuang Jen, Longtan (TW); Ping-Lin Kuo, Longtan (TW); Torng-Jinn Lee, Longtan (TW); Jeng-Shiung Jan, Longtan (TW)

(21) Appl. No.: 14/017,534

(22) Filed: Sep. 4, 2013

(51) Int. Cl. G01R 31/36

(52) U.S. Cl. CPC G01R 31/3679
USPC 324/426

(57) ABSTRACT

The present invention relates to a method for detecting lithium battery. In the present invention, the method for detecting lithium battery is provided for executing the two pulse load test and AC impedance analysis to determine not only whether the state of health (SOH) of lithium battery is working or not, but also the SOH of battery would be precisely estimated to obtain the precise SOH and to avoid detection error resulted in substantial waste of resources.

### BACKGROUND OF THE INVENTION

1. Technical Field

The present invention relates to battery detection, and more particularly to a method for detecting lithium battery which executes the two pulse load test and AC impedance analysis to determine whether the state of health (SOH) of lithium battery is working or not.

2. Description of Related Art

For complying the energy conservation and carbon reduction, the electric drives are gradually replacing traditional fossil fuel. In this case, the long-term use, the longevity and stability of battery would be very important. In the related art, the DC impedance measurement is mostly used to measure the impedance of a battery in open circuit voltage, and the AC impedance is used to measured half-cell battery during charging and discharging to determine whether the state of the electrolyte is broken or not, so the above mentioned measurement could only determine whether the battery is broken or not, but the state of health (SOH) of battery could not be precisely estimated.

At the present stage, battery management system has functions of supervising and balancing the voltage of the battery cell, but it could not determine the SOH of the battery. Generally, if the SOH of the battery used in electric vehicles is less than 70% (the charged capacity is less than 70% after charging), the battery must be eliminated because the general electric vehicles could no be driven by this kind of battery. However, although this kind of battery could not drive the electric vehicles, it still could be applied in other way. Thus the SOH of battery must be precisely estimated to avoid detection error resulted in substantial waste of resources.

Accordingly, in view of the conventional battery detection still have a shortcoming, the inventor of the present application has made great efforts to make inventive research thereon and eventually provided a method for detecting lithium battery.

### BRIEF SUMMARY OF THE INVENTION

The primary objective of the present invention is to provide a method for detecting lithium battery. By Executing the two pulse load test and AC impedance analysis to determine not only whether the state of health (SOH) of lithium battery is working or not, but also the SOH of battery would be precisely estimated to obtain the precise SOH and to avoid detection error resulted in substantial waste of resources.

Thus, for achieving the objective of the present invention, the inventors of the present invention propose a method for detecting lithium battery, comprising:

Step 1: connecting a battery management system and at least one set of lithium battery, wherein the battery management system would detect the cell voltage, State Of Charge (SOC) and equalize battery of the at least one set of lithium battery;

Step 2: Connecting a detector unit to the battery management system, wherein the detector unit comprises a processor unit and a memory unit;

Step 3: the processing unit executes the two pulse load test to the at least one set of lithium battery with different SOC, and then gets at least one voltage difference, and the pressure difference is stored in the memory unit;

Step 4: Calculating and determining the state of health (SOH) of the at least one set of lithium battery by using linear regression on the at least one voltage difference; and

Step 5: Executing the AC impedance analysis on the at least one set of lithium battery, and then comparing the result of the analysis with the SOH in the step 4 to precisely measure the SOH of the at least one set of lithium battery.

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is a block diagram of a system for detecting lithium battery according to the present invention;

FIG. 2 is a flowchart of a method for detecting lithium battery according to the present invention; and

FIG. 3 is a detail flowchart of the step 3 for the method for detecting lithium battery according to the present invention.

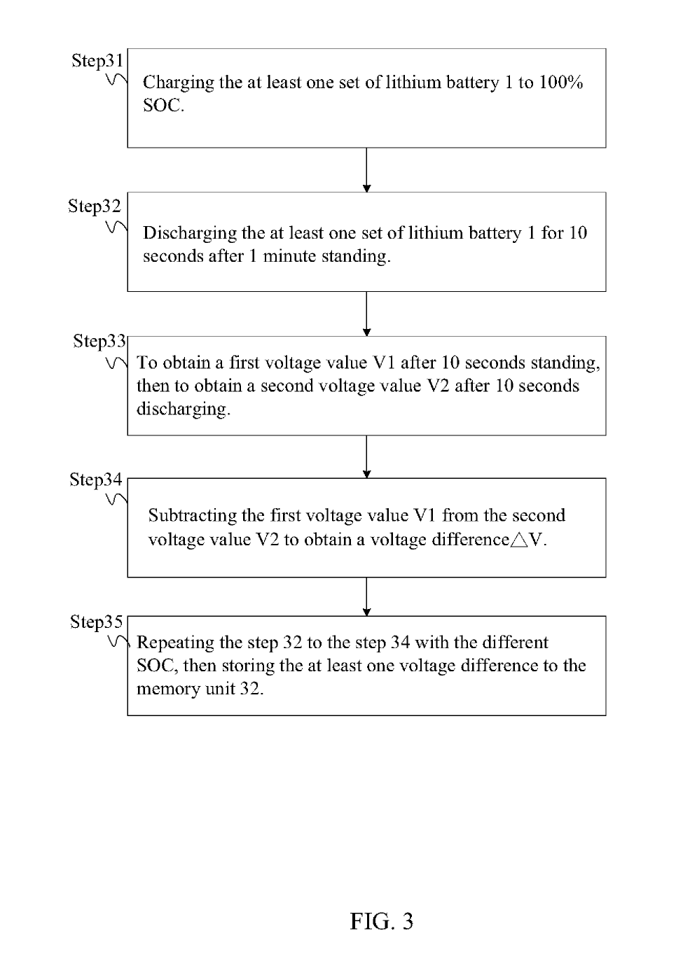

### DETAILED DESCRIPTION OF THE INVENTION

To more clearly describe a vibration energy harvest device according to the present invention, embodiments of the present invention will be described in detail with reference to the attached drawings hereinafter.

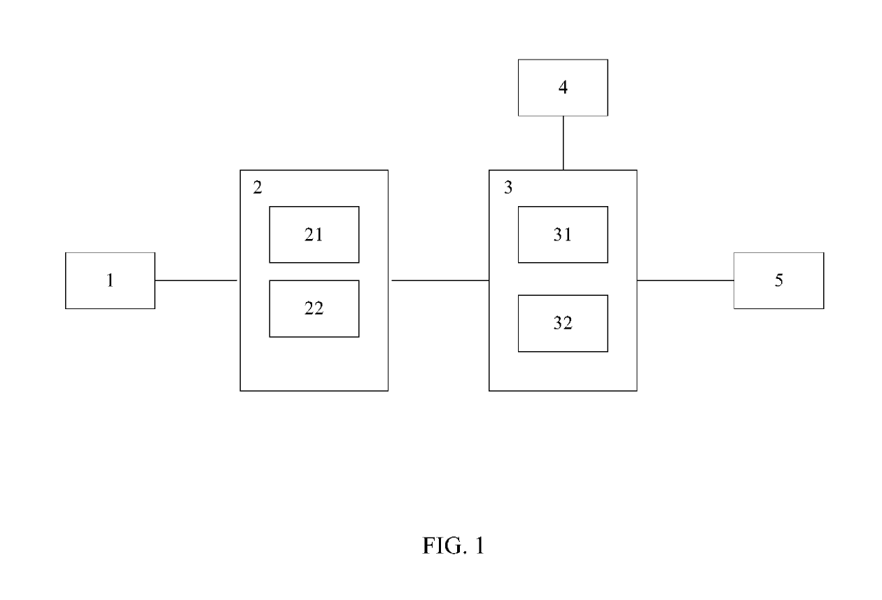

First of all, the system for detecting lithium battery will be described. With reference to FIG. 1, there is shown a block diagram of a system for detecting lithium battery according to the present invention. As shown in FIG. 1, the system for detecting lithium battery comprises: a set of lithium battery 1; a battery management system 2, which is connected to the set of lithium battery 1, wherein the battery management system 2 would detect the cell voltage, state of charge (SOC) and equalize battery of the set of lithium battery 1; in addition, the battery management system 2 further comprises a switch unit 21 and an ACD unit 22; and a detector unit 3, which is connected to the battery management system 2, wherein the detector unit 3 comprises a processor unit 31 and a memory unit 32, and in this embodiment, the detector unit 3 could be a computer; in addition, the detector unit 3 could be further connected to a display unit 4 and a central control unit 5.

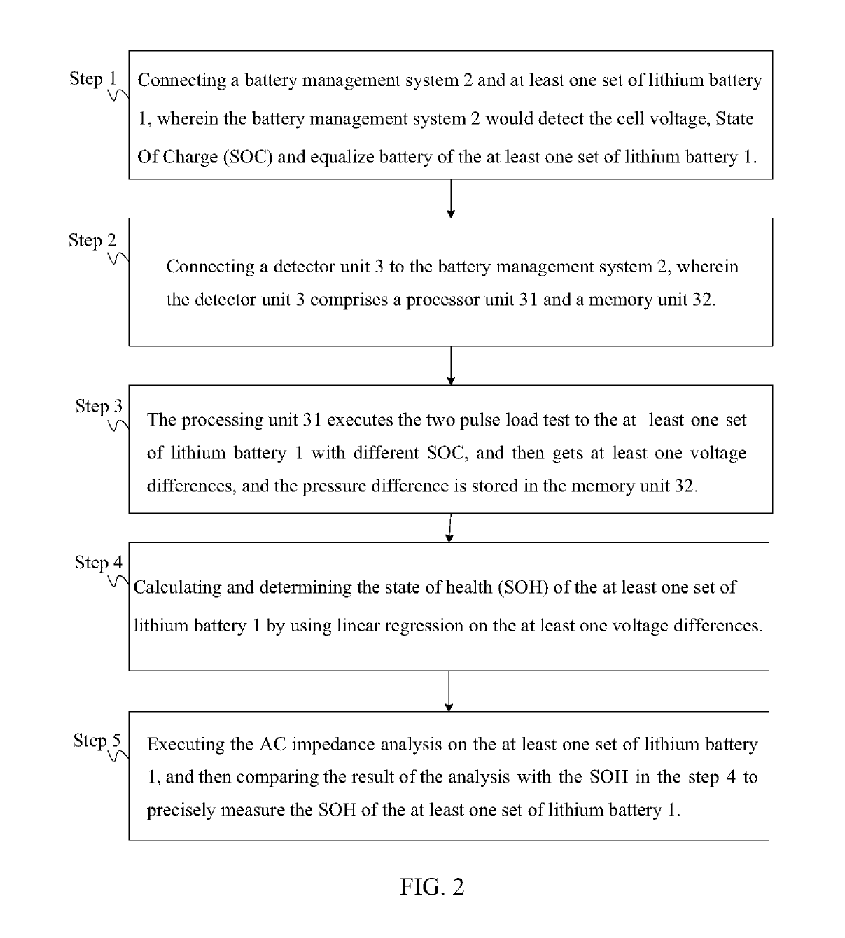

Therefore, through above descriptions, the structure of the system for detecting lithium battery has been introduced completely and clearly. Next, as shown in FIG. 2, which is a flowchart illustrating a method for detecting lithium battery according to the present invention. The steps of method for detecting lithium battery would be explained. The method for detecting lithium battery comprises:

Step 1: connecting the battery management system 2 and the set of lithium battery 1, wherein the battery management system 2 would detect the cell voltage, State Of Charge (SOC) and equalize battery of the set of lithium battery 1;

Step 2: Connecting a detector unit 3 to the battery management system 2, wherein the detector unit 3 comprises a processor unit 31 and a memory unit 32;

Step 3: the processing unit 31 executes the two pulse load test to the set of lithium battery 1 with different SOC, and then gets few voltage differences, and the voltage differences would be stored in the memory unit 32; wherein the step 3 further comprises following steps:

Step 31: Charging the set of lithium battery 1 to 100% SOC;

Step 32: Discharging the set of lithium battery 1 for 10 seconds after 1 minute standing;

Step 33: To obtain a first voltage value V₁ after 10 seconds standing, then to obtain a second voltage value V₂ after 10 seconds discharging;

Step 34: Subtracting the first voltage value V₁ from the second voltage value V₂ to obtain a voltage difference ΔV; and

Step 35: Repeating the step 32 to the step S34 with the different SOC, then storing these voltage difference to the memory unit 32, then continue the step 4.

Step 4: Calculating and determining the state of health (SOH) of the set of lithium battery 1 by using linear regression on the voltage differences; and

Step 5: Executing the AC impedance analysis on the set of lithium battery 1, wherein the AC impedance analysis is used to detect the impedance of the electrolyte, the electrode interface, the positive and the negative and then comparing the result of the analysis with the SOH in the step 4 to precisely measure the SOH of the at least one set of lithium battery 1.

Therefore, through above descriptions, the SOH of lithium battery 1 could be precisely measured. So that, according to above descriptions, the present invention has been completely and clearly disclosed; and in summary, the main advantage of the present invention is that by executing the two pulse load test and AC impedance analysis to determine not only whether the SOH of lithium battery is working or not, but also the SOH of battery would be precisely estimated to obtain the precise SOH and to avoid detection error resulted in substantial waste of resources.

The above description is made on embodiments of the present invention. However, the embodiments are not intended to limit scope of the present invention, and all equivalent implementations or alterations within the spirit of the present invention still fall within the scope of the present invention.

We claim:

1. A method for detecting lithium battery, comprising:
Step 1: connecting a battery management system and at least one set of lithium battery, wherein the battery management system would detect the cell voltage, State Of Charge (SOC) and equalize battery of the at least one set of lithium battery;
Step 2: Connecting a detector unit to the battery management system, wherein the detector unit comprises a processor unit and a memory unit;
Step 3: the processing unit executes the two pulse load test to the at least one set of lithium battery with different SOC, and then gets at least one voltage difference, and the pressure difference is stored in the memory unit;
Step 4: Calculating and determining the state of health (SOH) of the at least one set of lithium battery by using linear regression on the at least one voltage differences; and
Step 5: Executing the AC impedance analysis on the at least one set of lithium battery, and then comparing the result of the analysis with the SOH in the step 4 to precisely measure the SOH of the at least one set of lithium battery.

2. The method for detecting lithium battery of claim 1, wherein the step 3 further comprises:
Step 31: Charging the at least one set of lithium battery to 100% SOC;
Step 32: Discharging the at least one set of lithium battery for 10 seconds after 1 minute standing;
Step 33: To obtain a first voltage value V₁ after 10 seconds standing, then to obtain a second voltage value V₂ after 10 seconds discharging;
Step 34: Subtracting the first voltage value V₁ from the second voltage value V₂ to obtain a voltage difference ΔV; and
Step 35: Repeating the step 32 to the step 34 with the different SOC, then storing the at least one voltage difference to the memory unit.

3. The method for detecting lithium battery of claim 1, wherein the battery management system further comprises a switch unit and an ACD unit.

4. The method for detecting lithium battery of claim 1, wherein the detector unit is a computer.

5. The method for detecting lithium battery of claim 1, wherein the detector unit is further connected to a display unit.

6. The method for detecting lithium battery of claim 1, wherein the detector unit is further connected to a central control unit.

7. The method for detecting lithium battery of claim 1, wherein the AC impedance analysis is used to detect the impedance of the electrolyte, the electrode interface, the positive and the negative .

8. A system for detecting lithium battery comprising:
at least one set of lithium battery;
a battery management system, being connected to the at least one set of lithium battery, wherein the battery management system would detect the cell voltage, State Of Charge (SOC) and equalize battery of the at least one set of lithium battery; and
a detector unit, being connected to the battery management system, wherein the detector unit comprises a processor unit and a memory unit.

9. The system for detecting lithium battery of claim 8, wherein the battery management system further comprises a switch unit and an ACD unit.

10. The system for detecting lithium battery of claim 8, wherein the detector unit is a computer.

11. The system for detecting lithium battery of claim 8, wherein the detector unit is further connected to a display unit.

12. The system for detecting lithium battery of claim 8, wherein the detector unit is further connected to a central control unit.
